(19) United States
(12) Patent Application Publication
(10) Pub. No.: US 2024/0413196 A1
(43) Pub. Date: Dec. 12, 2024

(54) TERMINATION STRUCTURES FOR MOSFETS

(71) Applicant: SEMICONDUCTOR COMPONENTS INDUSTRIES, LLC, Scottsdale, AZ (US)

(72) Inventors: Sauvik CHOWDHURY, San Jose, CA (US); Zia HOSSAIN, Tempe, AZ (US); Joseph Andrew YEDINAK, Mountain Top, PA (US)

(73) Assignee: SEMICONDUCTOR COMPONENTS INDUSTRIES, LLC, Scottsdale, AZ (US)

(21) Appl. No.: 18/701,585

(22) PCT Filed: Sep. 11, 2023
(86) PCT No.: PCT/US2023/073897

§ 371 Date: Apr. 15, 2024

Related U.S. Application Data
(60) Provisional application No. 63/375,072, filed on Sep. 9, 2022.
(60) Provisional application No. 63/579,448, filed on Aug. 29, 2023.

(51) Int. Cl. H01L 29/06; H01L 29/16; H01L 29/49

(52) U.S. Cl. CPC H01L 29/0607; H01L 29/1608; H01L 29/4916

(57) ABSTRACT

Shielded gate semiconductor devices are disclosed for use in high power applications such as electric vehicles and industrial applications. The devices are formed as mesa (106)/trench (400) structures in which shielded gate electrodes are formed in the trenches. Various trench structures (400, 500, 600, 700) are presented that include tapered portions (401) and end tabs (502, 602, 702, 802) that can be beneficial in managing the distribution of electric charge and associated electric fields. The tapered trenches (400) can be used to increase and stabilize breakdown voltages in a termination region (104) of a semiconductor die (100).

### CROSS-REFERENCE TO RELATED APPLICATIONS

This patent application claims the benefit of U.S. Provisional Patent Application No. 63/375,072, filed on Sep. 9, 2022, and titled “Termination Structures for MOSFETs,” and U.S. Provisional Patent Application 63/579,448, filed on Aug. 29, 2023, and titled “Tapered Trench Termination Structure for Gate Metal-Oxide-Semiconductor Field-Effect Transistor (MOSFET),” both of which are incorporated by reference herein in their entireties.

### TECHNICAL FIELD

This description relates to power semiconductor devices. More specifically, this description relates to termination structures for shielded gate metal oxide semiconductor field effect transistors (MOSFETs).

### BACKGROUND

Semiconductor device assemblies, e.g., chip assemblies, that include high power semiconductor devices can be used in various applications, including electric vehicles (EVs), hybrid electric vehicles (HEVs), and industrial applications. High power modules may operate, for example, at voltages exceeding 100 V, and may carry large currents, e.g., 200 A, as opposed to, for example, computer applications that operate at voltages in the range of about 1V to about 15 V. Power transistors can include, for example, insulated-gate bipolar transistors (IGBTs), shielded gate metal oxide semiconductor field effect transistors (shielded gate MOSFETs), and double-diffused metal-oxide-semiconductor (DMOS) devices. Some shielded gate MOSFETs can be formed in a silicon carbide (SiC) substrate.

### SUMMARY

In some aspects, the techniques described herein relate to an apparatus including: a trench having a first portion in an active region and a second portion in a termination region, the trench having a vertical depth within a semiconductor substrate and having a longitudinal axis extending from within the active region into the termination region; a dielectric lining disposed in the trench; and a conductive electrode disposed in the trench over the dielectric lining, the conductive electrode having, along the longitudinal axis, a uniform shape within the first portion, and a tapered shape within the second portion.

In some aspects, the techniques described herein relate to an apparatus, further including a tab intersecting an end of the second portion, the tab extending in a direction transverse to the longitudinal axis.

In some aspects, the techniques described herein relate to an apparatus, wherein the tab is substantially symmetric about the longitudinal axis.

In some aspects, the techniques described herein relate to an apparatus, wherein the conductive electrode includes polysilicon.

In some aspects, the techniques described herein relate to an apparatus, wherein the semiconductor substrate includes silicon carbide.

In some aspects, the techniques described herein relate to an apparatus, being a shield structure of a shielded metal oxide semiconductor field effect transistor.

In some aspects, the techniques described herein relate to a device, including: a substrate having a diffusion region formed therein; a source in the diffusion region; a drain in the diffusion region; and a shield structure formed in a trench in the substrate, the trench having a dielectric liner, wherein the shield structure extends out from within the diffusion region and tapers to a terminus.

In some aspects, the techniques described herein relate to a device, wherein the terminus is a point.

In some aspects, the techniques described herein relate to a device, wherein the terminus includes at least one of a tab, an extension, and a reverse taper.

In some aspects, the techniques described herein relate to a device, wherein the terminus includes a tab that extends in a direction orthogonal to the trench.

In some aspects, the techniques described herein relate to a device, wherein an aspect ratio characterizing a maximum width of the shield structure in the diffusion region and a minimum width of the shield structure at the terminus is about 3:1.

In some aspects, the techniques described herein relate to a device, wherein a first side of the shield structure is tapered, and a second side, opposite the first side, is straight.

In some aspects, the techniques described herein relate to a structure in a substrate, the structure including: a central shield structure; a first shield structure adjacent to one side of the central shield structure; and a second shield structure adjacent to an opposite side of the central shield structure, wherein the central shield structure is not tapered, the first shield structure has a tapered first side, and the second shield structure has a tapered second side.

In some aspects, the techniques described herein relate to a structure, wherein the first shield structure includes a first end tab extending laterally outward from the tapered first side and the second shield structure includes a second end tab extending laterally outward from the tapered second side.

In some aspects, the techniques described herein relate to a structure, wherein the first end tab and the second end tab have rounded corners.

In some aspects, the techniques described herein relate to a structure, wherein each one of the central shield structure, the first shield structure, and the second shield structure extends into the substrate to a prescribed depth.

In some aspects, the techniques described herein relate to a structure, wherein the prescribed depth varies along a length of the shield structure.

In some aspects, the techniques described herein relate to a structure, wherein the prescribed depth is in a range of about 1.0 μm to about 15.0 μm.

In some aspects, the techniques described herein relate to a structure, wherein the first shield structure and the second shield structure each have a minimum depth coinciding with a maximum taper.

In some aspects, the techniques described herein relate to a structure, wherein each of the shield structures has a width in a range of about 0.1 μm to about 1.0 μm.

### BRIEF DESCRIPTION OF THE DRAWINGS

FIG. 1A is a top plan view of an array of shielded gate MOSFET electrodes formed in tapered trenches, according to implementations of the present disclosure.

FIG. 1B is a perspective view of a mesa structure formed between two adjacent tapered trenches, according to implementations of the present disclosure.

FIGS. 2A-2D are views of surface gate electrodes formed in tapered trenches, according to implementations of the present disclosure.

FIGS. 3A-3C are views of recessed gate electrodes formed in tapered trenches, according to implementations of the present disclosure.

FIGS. 4A-4F illustrate shielded electrodes formed in trenches that taper to a point, according to implementations of the present disclosure.

FIGS. 5A-5F illustrate shielded electrodes formed in trenches that taper to a tab, according to implementations of the present disclosure.

FIGS. 6A-6F illustrate shielded electrodes formed in trenches that taper to a narrowed region and a tab, according to implementations of the present disclosure.

FIGS. 7A-7F illustrate shielded electrodes formed in trenches formed with a double taper, according to implementations of the present disclosure.

FIGS. 8A-8G illustrate shielded electrodes formed in trenches that taper to a tab and an oxide trench, according to implementations of the present disclosure.

FIGS. 9A-9G illustrate shielded electrodes formed in trenches having a single-sided taper with a single-sided tab, according to implementations of the present disclosure.

FIG. 10 is a plot of breakdown voltage as a function of trench design, according to implementations of the present disclosure.

FIG. 11 is a cross-sectional view of a shielded gate MOSFET in the active region of a semiconductor die, according to implementations of the present disclosure.

Aspects of the present disclosure are best understood from the following detailed description when read with the accompanying figures. It is noted that, in accordance with common practice in the industry, various features are not necessarily drawn to scale. Dimensions of the various features may be arbitrarily increased or reduced for clarity of discussion. In the drawings, like reference symbols may indicate like and/or similar components (elements, structures, etc.) in different views. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are provided for context between related views. Also, not all like elements in the drawings are specifically referenced with a reference symbol when multiple instances of an element are illustrated.

### DETAILED DESCRIPTION

Power semiconductor devices such as shielded gate MOSFETs and IGBTs can be implemented in a semiconductor die having an active area in which an array of semiconductor mesa structures (e.g., mesas) alternates with trench structures (e.g., trenches). Such mesa/trench structures can be formed at a top surface of the semiconductor die. The active area may be a diffusion area containing dopants. An array of parallel shielded gate electrodes can be formed in the trenches, by lining the trenches with an insulator, e.g., a dielectric material, and then filling the trenches with a conductive material (e.g., polysilicon or metal). Meanwhile, other elements of the power device, e.g., a body region, source regions, drain regions, heavy body regions, collector regions, emitter regions, base regions, etc., can be formed in the mesas that are located between, and are defined by, the trenches. The shielded gate electrodes can be electrically coupled to an energy source of the power device, e.g., a source potential of a power IGBT or power MOSFET.

An array of such devices can include hundreds or thousands of elongated mesas and shielded gate electrodes (e.g., filled trenches) that support high voltages, e.g., up to about 250 V. The devices can have an ON state in which a desired current flows through the device, an OFF state in which current flow is substantially blocked in the device, and a breakdown state in which an undesired current flows due to an excess off-state voltage being applied between electrodes of the device. The voltage at which breakdown is initiated is called the breakdown voltage. The configuration of the mesas and trenches can result in a variety of trade-offs between achieving desirable ON-state characteristics, relatively high breakdown voltage, and desirable switching characteristics.

The semiconductor die can also include a termination region, or field termination area, disposed around, or adjacent to, the active area. In some implementations, the termination region borders the active area. In some implementations, the termination region partially or completely surrounds the active area. Electrodes, e.g., shield electrodes from the active area can extend into the termination region to form termination structures, e.g., shield structures. In some implementations, the shield electrodes can be coupled to source terminals. In some implementations, the shield electrodes can be coupled to gate terminals. In some implementations, it is desirable for the breakdown voltage to be higher in the termination region than in the active region.

One problem that arises in the termination region is that charge can accumulate at the ends of the shielded gate electrodes, giving rise to large electric fields. The termination structures can be designed to reduce or minimize electric fields around the active area, and may not be configured to conduct current during operation of the power semiconductor device implemented in the active region. The electric fields in the termination region can be altered or controlled by changing the materials and/or the shapes and dimensions of the termination structures. By controlling the field strength in the termination region, voltage breakdown can be avoided. A high breakdown voltage, or voltage rating, of the device can thus be achieved, or at least assisted, by the effectiveness of such termination structures.

Various breakdown processes can occur in the termination region that can significantly lower the breakdown voltage (holding voltage, voltage rating) and thus compromise an associated power device. For example, differences in charge balance (e.g. a large imbalance between available charge at a surface of a mesa in the termination region and available charge at a bottom of the mesa in the termination region) can affect such breakdown voltages. For instance, if an amount of available charge at a surface of a mesa is significantly less, e.g., by an order of magnitude or more, than an amount of available charge at the bottom of the mesa, the resulting charge imbalance can cause rapid depletion of the termination region at its semiconductor mesa surfaces when an associated power device is in an off-state. This rapid depletion can cause a depletion field from the active area to extend to the end, almost to the end, or beyond the end, of the termination structure (e.g., beyond the ends of shield electrode filled trenches in the termination region) at a voltage below a desired breakdown voltage for the power semiconductor device. Such rapid depletion can result in a breakdown process occurring in the termination region (e.g., due to impact ionization) and, as a result, reduce a breakdown voltage (holding voltage, voltage rating, etc.) of the associated power device below a desired level.

A number of factors can affect charge balance in such power devices. For instance, certain design features and processing characteristics can be implemented to improve device performance by affecting charge balance in the termination region. For example, as noted above, spacing between trenches (which results in reduced mesa widths) and use of retrograde doping in a semiconductor region, e.g., by an epitaxial semiconductor layer, in which the trenches and mesas are defined, can increase such charge imbalance e.g., by causing a greater imbalance between a top and a bottom of a given semiconductor mesa. Use of a retrograde doped semiconductor material (e.g., an epitaxial silicon layer) can result in associated mesas having lower doping in their upper portions (e.g., at and/or near their upper surfaces) than at the base of the mesas (e.g., at and/or near the trench bottoms defining the mesas). Further, formation of trenches with sloped sidewalls (e.g. with a vertical taper) produces mesas that are narrower at the top than at the base. This variation in width between the tops of the mesas and the base of the mesas can further increase charge imbalance from the upper portions of the mesas to the lower portions of the mesas.

Changing the mask design of the gate electrodes/trenches in the termination region can prevent a breakdown process from occurring below a desired breakdown voltage of an associated power semiconductor device. For example, increasing the spacing between adjacent gate electrodes can reduce the chance of breakdown. One advantage of this approach over altering the mesa doping profiles is that changes to the dopant implantation process are avoided. One way to increase the spacing between gate electrodes in the termination region is to taper the electrode widths by horizontally tapering the trench structures that define the electrode widths. However, if the trench tapers to a point, the electric field will be concentrated at the pointed tip of the electrode. Introducing a tab structure at the end of the gate electrode can mitigate this effect.

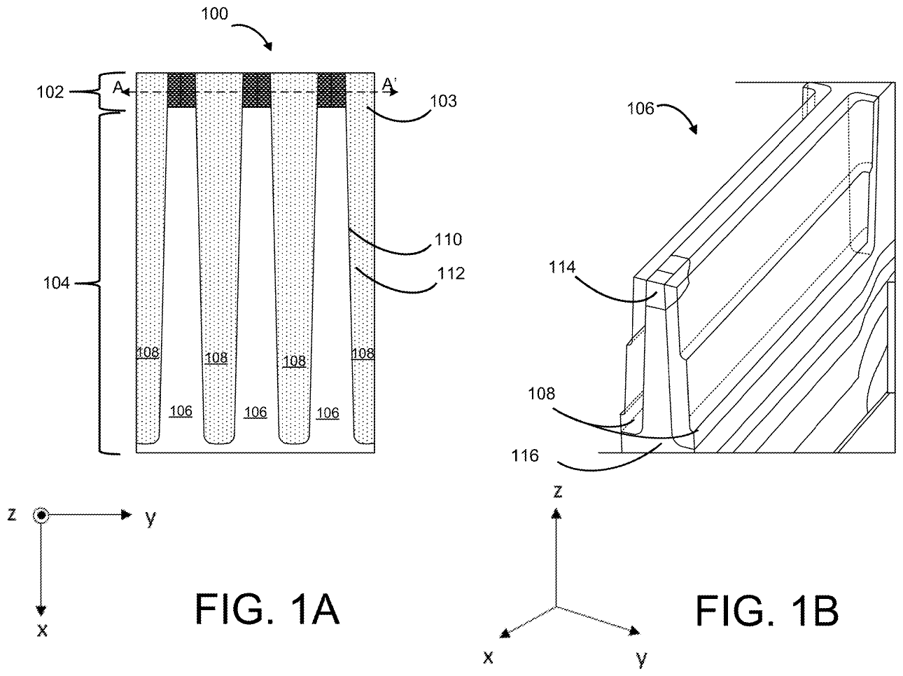

FIG. 1A is a top-down plan view of a semiconductor die 100 in which shielded gate MOSFET devices are formed in a substrate, in accordance with some implementations of the present disclosure. The semiconductor die 100 includes an active area 102 and a termination region 104, and a boundary 103 separating the active area 102 from the termination region 104.

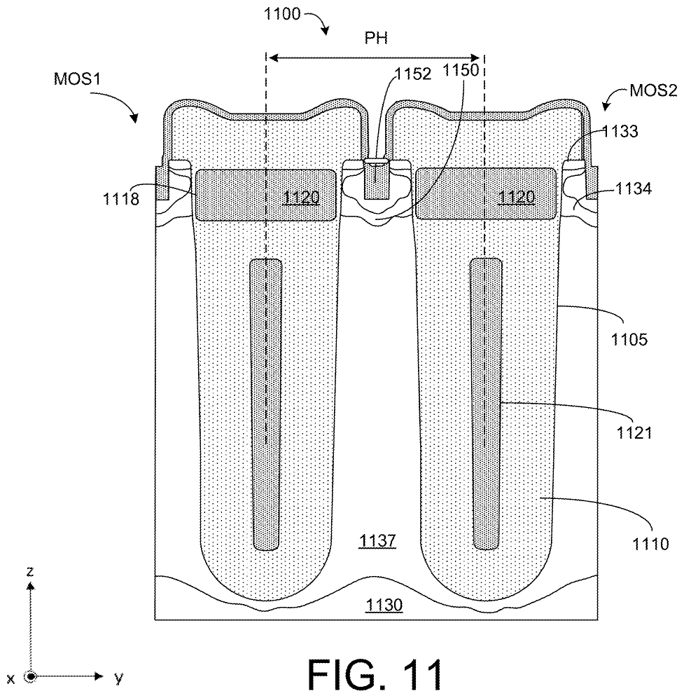

An array of mesa/trench structures extends from the active area 102 into the termination region 104. The array of mesa/trench structures includes a plurality of mesas 106 alternating with shield electrodes 108. In some implementations, the array is characterized by a pitch, e.g., center-to-center electrode distance, of about 2 microns within a die that has a length in a range of several thousand microns to about 10,000 microns. The active area 102 can be a doped region, e.g., a p-well or n-well region, wherein the mesas 106 within the doped region serve as source/drain regions of the shielded gate MOSFET devices. Examples of such devices disposed in the active area 102 are shown and described with reference to FIG. 11. Doping profiles within the mesas 106 in the active area 102, and in the termination region 104, can be designed to optimize charge distributions to achieve various operational specifications of the device. In some implementations, dopant concentrations within the mesas 106 range from about 1.0×10¹⁵ cm⁻³ to about 1.0×10¹⁸ cm⁻³ within the active area and from about 1.0×10¹⁵ cm⁻³ to about 1.0×10¹⁸ cm⁻³ within the termination region. The boundary 103 can be referred to as a body junction. When the active area 102 is p-doped for example, the boundary 103 is called a p-body junction.

The shield electrodes 108 can be formed by removing portions of the doped material in the active area 102, and by removing portions of the substrate in the termination region 104 to form trenches. The trenches can then be lined with an insulating material 110, e.g., a dielectric such as an oxide, and then filled with a conducting material 112, e.g., polysilicon or metal, to form the shield electrodes 108. Thus, the shape and dimensions of the shield electrodes 108 are determined by the shape and dimensions of the trenches. The shield electrodes 108 as shown in FIG. 1A are tapered, that is, the widths of the shield electrodes 108 are progressively narrowed along the y-direction by forming tapered trenches. Tapering the shield electrodes 108 tends to concentrate more charge at the tapered ends, thus increasing charge laterally away from the p-body junction at the boundary 103, and creating a more uniform electric field. In some implementations, the widths of the shield electrodes 108 at the boundary 103 of the active area 102 can range from about 0.1 μm to about 1.0 μm, tapering to a narrow width at the terminus of the shield electrode 108, in a range of about xxx 0.05 μm to about xxx.0.3 μm. In some implementations, an aspect ratio of the maximum width to the minimum width of the tapered shield electrode 108 can be about 3:1.

FIG. 1B is a perspective view of a mesa 106 (e.g., one of the mesas shown in FIG. 1A), in accordance with some implementations of the present disclosure. The mesa 106 extends upward in the z-direction between adjacent parallel trenches. In some implementations, the mesa 106 can be tapered vertically, along its height in the z-direction, so that a top 114 of the mesa is narrower than a base 116 of the mesa, as shown in FIG. 1B. In some implementations, the height of the mesa 106 is in a range of about 1.0 microns to about 20.0 microns. In some implementations, the width of the mesa 106 tapers vertically from about 1.0 μm at the base to about 0.4 μm at the top,

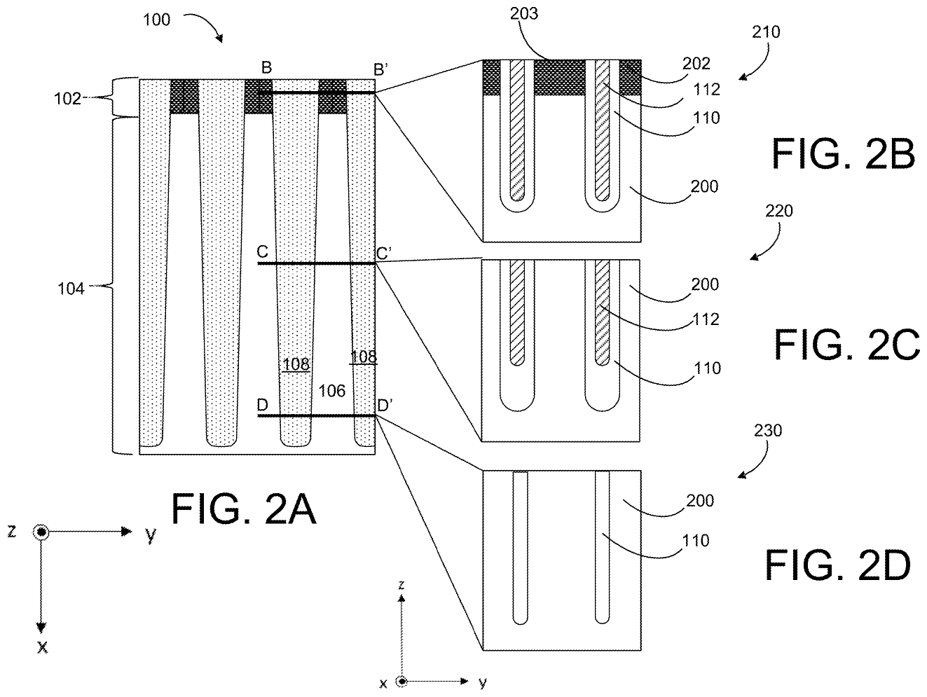

FIG. 2A reproduces the top-down plan view of FIG. 1A to show cross-sectional cuts at different locations along the tapered length (e.g., along the x-axis) of shield electrodes 108 at the surface of the semiconductor die, in accordance with some implementations of the present disclosure.

FIG. 2B is a cross-sectional view along the cut line B-B′ through a pair of parallel shield electrodes 108 shown in FIG. 2A, in accordance with some implementations of the present disclosure. The cross-sectional view shown in FIG. 2B is within the active area 102, at the wide end of the tapered trench near the body junction at the boundary 103. FIG. 2B shows a substrate 200 and a doped region 202 near a top surface 203 of the substrate 200. In some implementations, the substrate 200 is a silicon substrate. In some implementations, the substrate 200 includes silicon carbide (SiC). In some implementations, the substrate 200 can include an epitaxial layer, e.g., a layer of epi silicon. FIG. 2B further illustrates the insulating material 110 and the conducting material 112 inside the parallel trenches forming the shield electrodes 108. FIG. 2B shows that in the active area 102, at the widest part of the trench, the thickness of the insulating material 110 lining the trench is substantially uniform. In some implementations, the thickness of the substantially uniform lining can be in a range of about 0.05 μm to about 1.5 μm. Accordingly, the volume of conductive material 112 inside the trench is maximized, creating a full shield electrode 210 extending almost to the bottom of the trench at points along the y-axis closest to the body junction.

FIG. 2C is a cross-sectional view along the cut line C-C′ of the pair of parallel shield electrodes 108 shown in FIG. 2A, in accordance with some implementations of the present disclosure. The cross-sectional view shown in FIG. 2C is within the termination region 104, at a location along the length of the tapered trench where the trench has a medium-sized width. FIG. 2C shows that in this location within the termination region 104, the thickness of the insulating material 110 lining the trench is substantially uniform on the sides, but there is more insulating material 110 at the bottom of the trench, which limits the amount of conducting material 112 that can be deposited into the trench. Accordingly, the volume of conductive material 112 inside the trench is less than the volume of conducting material 112 in the wider trench shown in FIG. 2B, creating a partial shield electrode 220. In some implementations, the thickness of the insulating material 110 at the base of the trenches can be in a range of about 0.05 μm to about 1.5 μm.

FIG. 2D is a cross-sectional view along the cut line D-D′ near the tips of the pair of parallel shield electrodes 108 shown in FIG. 2A, in accordance with some implementations of the present disclosure. The cross-sectional view shown in FIG. 2D is within the termination region 104, at the narrow end of the tapered trench. FIG. 2D shows that, because the trench is so narrow, the insulating material 110 that is intended to line the trench actually fills the entire trench. Consequently, the trench fill is pinched off so that there is no conducting material 112 inside the trenches near the tips of the shield electrodes 108, creating an oxide-filled trench 230. In some implementations, the oxide filled trench 230 can have a width in a range of about 0.1 μm to about 3.0 μm and a depth in a range of about 0.5 μm to about 15 μm.

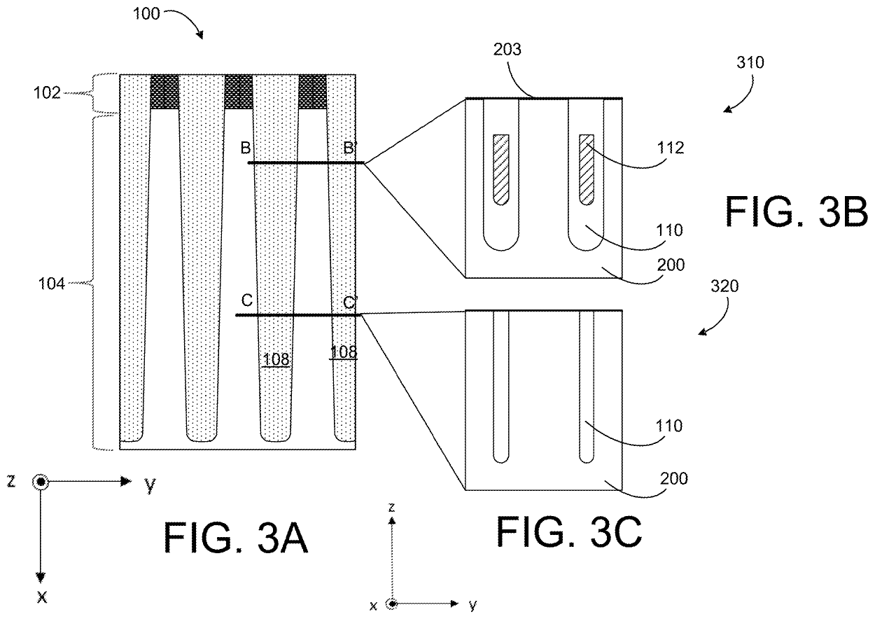

FIG. 3A shows a top-down plan view with cross-sectional cuts at different locations along the tapered length (e.g., along the x-axis) of shield electrodes 108 that are recessed below a top surface of the semiconductor die, in accordance with some implementations of the present disclosure.

FIG. 3B is a cross-sectional view along the cut line B-B′ of the pair of parallel shield electrodes 108 shown in FIG. 3A, in accordance with some implementations of the present disclosure. The cross-sectional view shown in FIG. 3B is within the termination region 104, at a location along the length of the tapered trench where the trench has a medium-sized width. FIG. 3B shows that in this location within the termination region 104, the thickness of the insulating material 110 lining the trench is substantially uniform on the sides, but there is more insulating material 110 at the bottom of the trench, which limits the amount of conducting material 112 that can be deposited into the trench, similar to the cut C-C′ shown in FIG. 2C. However, in the implementation shown in FIG. 3B, the conducting material 112 is recessed away from the top surface 203, and the top part of the trench is filled with the insulating material 110. Accordingly, the volume of conductive material 112 inside the trench is less than the volume of conducting material 112 in the wider trench shown in FIG. 2B, creating a recessed partial shield electrode 310. In some implementations, the length of the recessed conducting material 112 can be in a range of about 0.2 μm to about 2.0 μm.

FIG. 3C is a cross-sectional view along the cut line C-C′ of the pair of parallel shield electrodes 108 shown in FIG. 3A, in accordance with some implementations of the present disclosure. The cross-sectional view shown in FIG. 3C is within the termination region 104, at a location along the length of the tapered trench that is more tapered than along the cut line B-B′, but where the trench still has a medium-sized width. FIG. 3C shows that, because the trench is so narrow, the insulating material 110 that is intended to line the trench actually fills the entire trench. Consequently, the trench fill is pinched off so that there is no conducting material 112 inside the trenches near the tips of the shield electrodes 108, creating an oxide-filled trench 320. In some implementations, the oxide filled trench 320 can have a width in a range of about 0.1 μm to about 3.0 μm and a depth in a range of about 0.5 μm to about 17 μm.

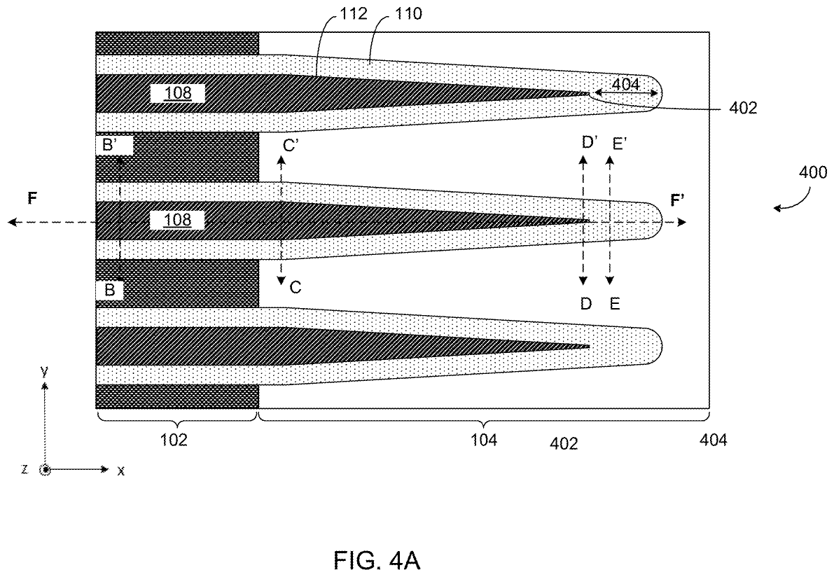

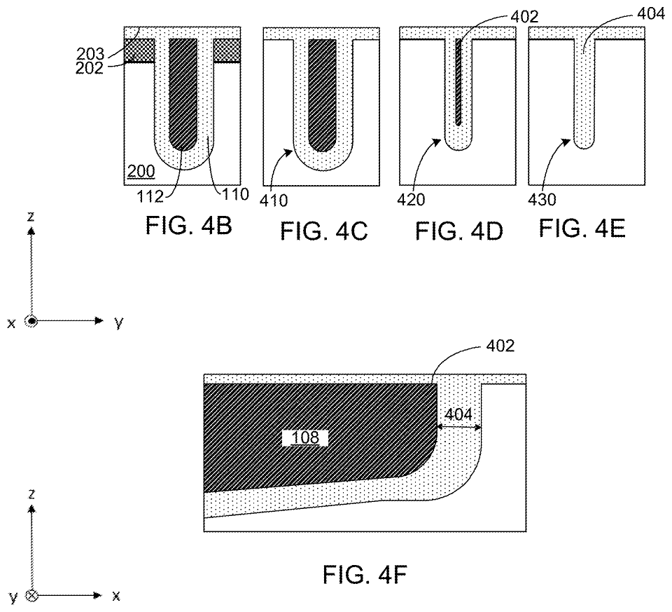

FIGS. 4A-9G show implementations of different tapered trench designs having various features to shape the charge distribution and associated electric fields in the termination region. It is evident in FIGS. 4A-9G that, in some implementations, modifying the trench pattern as seen in the top plan views of the shield electrodes 108 defines a prescribed trench depth as seen in the corresponding cross-sectional views. For example, as the trench width is tapered, the trench depth can become shallower. This effect can be due to one or more constraints, or interactions, within in the fabrication process, e.g., in the patterning (e.g., etching) process, or in the deposition process used to fill the trenches.

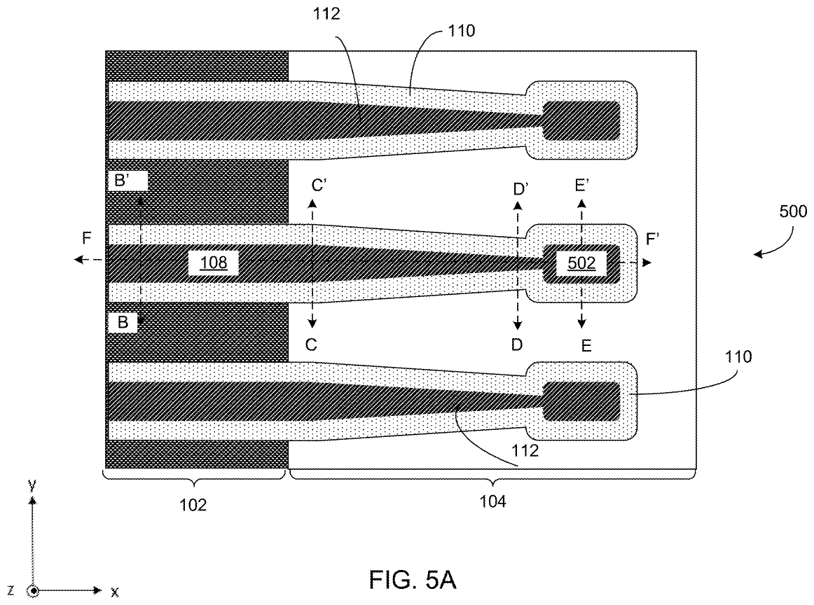

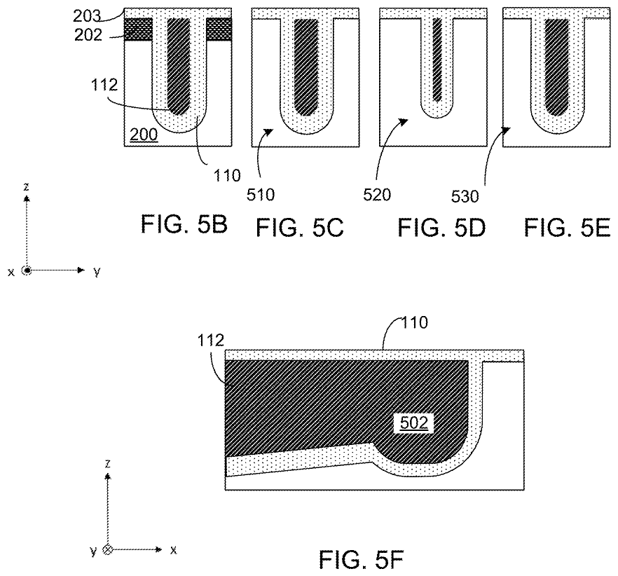

FIGS. 4A-4F are views of tapered trenches 400, in accordance with some implementations of the present disclosure. The tapered trenches 400 e.g., filled tapered trenches that serve as the shield electrodes 108, may represent a larger array of many tapered trench structures. In the implementation shown in FIGS. 4A-4F, each tapered trench 400 has a tapered portion 401 that tapers to a point 402, thus increasing the spacing between the trenches, and reducing the probability of breakdown due to rapid depletion at the mesa surface from the active area resulting in a high electric field at the end of the shield electrodes 108. One drawback, however, of the tapered portion 401 shown in FIGS. 4A-4F, is that the point 402 tends to concentrate electric charge, giving rise to a high electric field near the trench bottom, and may present an injection point, e.g., a charge injection point, at the end of the trench. Alternative implementations shown in FIGS. 5A-9G and described below can mitigate this effect while preserving the benefit of a tapered trench.

FIG. 4A is a top-down plan view of a group of three tapered trenches 400, in accordance with some implementations of the present disclosure. FIG. 4A shows the active area 102 and the termination region 104. The central tapered trench in FIG. 4A shows cross-sectional cuts at different locations along the tapered length (e.g., along the x-axis) of the central shield electrode 108. The cut lines correspond to the cross-sectional views shown in FIGS. 4B, 4C, 4D, and 4E. For example, cut line B-B′ corresponds to the transverse cross-sectional view shown in FIG. 4B; cut line C-C′ corresponds to the transverse cross-sectional view shown in FIG. 4C, and so on. Cut line F-F′ corresponds to a longitudinal cross-sectional view shown in FIG. 4F, wherein the cut line F-F′ is aligned with a longitudinal axis of the tapered trench, whereas the other cut lines, e.g., transverse cut lines, are aligned orthogonal to the longitudinal axis.

FIG. 4B is a cross-sectional view along the cut line B-B′ of the central tapered trench shown in FIG. 4A, in accordance with some implementations of the present disclosure. The cross-sectional view shown in FIG. 4B is within the active area 102, at the wide end of the tapered trench. FIG. 4B shows a substrate 200 and a doped region 202 near a top surface 203 of the substrate 200. In some implementations, the doped region 202 in the active area 102 can be a p-well. In some implementations, the substrate 200 may include an epitaxial layer, e.g., a layer of n-type epi silicon. FIG. 4B further illustrates the insulating material 110 and the conducting material 112 inside the parallel trenches forming the shield electrodes 108. FIG. 4B shows that, in the active area 102 at the widest part of the tapered trench, the thickness of the insulating material 110 lining the trench is substantially uniform. In some implementations, the thickness of the substantially uniform lining can be in a range of about 0.05 μm to about 1.5 μm. Accordingly, the volume of conductive material 112 inside the trench is maximized, creating a full shield electrode extending almost to the bottom of the trench. The internal structure of the tapered trench at the wide end as shown in FIG. 4B thus is similar to the example shown in FIG. 2B.

FIG. 4C is a cross-sectional view along the cut line C-C′ of the central tapered trench shown in FIG. 4A, in accordance with some implementations of the present disclosure. The cut line C-C′ is located outside the active area 102, in the termination region 104, but still coincides with the widest portion of the tapered trench. Consequently, the cross-sectional view shown in FIG. 4C shows a full shield electrode 410, similar to the cross-sectional view shown in FIG. 4B, except that the doped region 202 is not present in FIG. 4C.

FIG. 4D is a cross-sectional view along the cut line D-D′ of the central tapered trench shown in FIG. 4A, in accordance with some implementations of the present disclosure. The cut line D-D′ coincides with the pointed tip of the tapered trench. FIG. 4D shows that in this location within the termination region 104, the thickness of the insulating material 110 lining the trench is substantially uniform on the sides, but there is more insulating material 110 at the bottom of the trench, which limits the amount of conducting material 112 that can be deposited into the trench. Accordingly, the volume of conductive material 112 inside the trench is less than the volume of conducting material 112 in the wider portion of the trench shown in FIGS. 4B and 4C, creating a partial shield electrode 420. In some implementations, the thickness of the insulating material 110, e.g., shield oxide, at the base of the trenches can vary based on the trench critical dimension (CD) and/or oxide thickness variation incurred in the oxide liner growth or deposition process. Variation in the oxide thickness can cause instability in the breakdown voltage.

FIG. 4E is a cross-sectional view along the cut line E-E′ of the central tapered trench shown in FIG. 4A, in accordance with some implementations of the present disclosure. The cut line E-E′ coincides with oxide beyond the pointed tip of the tapered trench, in a pinch-off region 404 that extends from the point 402 to the end of the trench. FIG. 4E shows that the insulating material 110 that is intended to line the trench actually fills the entire trench in the pinch-off region 404. Consequently, there is no conducting material 112 inside the trenches beyond the tips of the shield electrodes 108, creating an oxide-filled trench 430. In some implementations, the oxide filled trench 430 can have a width in a range of about 0.1 μm to about 3.0 μm and a depth in a range of about 0.5 μm to about 17.0 μm. In some implementations, the pinch-off region 404 can vary significantly among the parallel trenches.

FIG. 4F is a cross-sectional view along the cut line F-F′, in accordance with some implementations of the present disclosure. The cut line F-F′ is aligned with the length of the central tapered trench shown in FIG. 4A, along the x-axis. FIG. 4F shows the depth of the trench gradually decreasing along the taper until the shield electrode 108 is pinched off at the right side of FIG. 4F, at the point 402. The remainder of the trench structure, in the pinch-off region 404, is filled with the insulating material 110.

FIGS. 5A-5F are views of tapered trenches 500, in accordance with some implementations of the present disclosure. The tapered trenches 500 e.g., filled tapered trenches that serve as the shield electrodes 108, may represent a larger array of many tapered trench structures. In the implementation shown in FIGS. 5A-5F, each trench tapers to a tab 502. The tab 502, by intersecting the end of the trench, provides a wider trench end that reduces the electric field strength at the end of the trench, thereby increasing the breakdown voltage. In some implementations, the tab 502 reduces the chance of an injection point occurring at the end of the tapered trench. The tab 502 may also be more easily reproduced than a point, and the tab 502 can reduce variability in the lengths of the tapered trenches.

FIG. 5A is a top-down plan view of a group of three tapered trenches 500, in accordance with some implementations of the present disclosure. FIG. 5A shows the active area 102 and the termination region 104. The central tapered trench in FIG. 5A shows cross-sectional cuts at different locations along the tapered length (e.g., along the x-axis) of the central shield electrode 108. The cut lines correspond to the cross-sectional views shown in FIGS. 5B, 5C, 5D, and 5E. For example, cut line B-B′ corresponds to the transverse cross-sectional view shown in FIG. 5B; cut line C-C′ corresponds to the transverse cross-sectional view shown in FIG. 5C, and so on. Cut line F-F′ corresponds to a longitudinal cross-sectional view shown in FIG. 5F, wherein the cut line F-F′ is aligned with a longitudinal axis of the tapered trench, whereas the other cut lines, e.g., transverse cut lines, are aligned orthogonal to the longitudinal axis.

FIG. 5B is a cross-sectional view along the cut line B-B′ of the central tapered trench shown in FIG. 5A, in accordance with some implementations of the present disclosure. The cross-sectional view shown in FIG. 5B is within the active area 102, at the wide end of the tapered trench. FIG. 5B shows a substrate 200 and a doped region 202 near a top surface 203 of the substrate 200. In some implementations, the doped region 202 in the active area 102 can be a p-well. In some implementations, the substrate 200 may include an epitaxial layer, e.g., a layer of n-type epi silicon. FIG. 5B further illustrates the insulating material 110 and the conducting material 112 inside the parallel trenches forming the shield electrodes 108. FIG. 5B shows that, in the active area 102 at the widest part of the tapered trench, the thickness of the insulating material 110 lining the trench is substantially uniform. In some implementations, the thickness of the substantially uniform lining can be in a range of 0.05 μm to about 1.5 μm. Accordingly, the volume of conductive material 112 inside the trench is maximized, creating a full shield electrode extending almost to the bottom of the trench. The internal structure of the tapered trench at the wide end as shown in FIG. 5B thus is similar to the example shown in FIG. 2B.

FIG. 5C is a cross-sectional view along the cut line C-C′ of the central tapered trench shown in FIG. 5A, in accordance with some implementations of the present disclosure. The cut line C-C′ is located outside the active area 102, in the termination region 104, but still coincides with the widest portion of the tapered trench. Consequently, the cross-sectional view shown in FIG. 5C shows a full shield electrode 410, similar to the cross-sectional view shown in FIG. 5B, except that the doped region 202 is not present in FIG. 5C.

FIG. 5D is a cross-sectional view along the cut line D-D′ of the central tapered trench shown in FIG. 5A, in accordance with some implementations of the present disclosure. The cut line D-D′ coincides with the narrow end of the tapered trench. FIG. 5D shows that in this location within the termination region 104, the trench is not as deep in the tapered region. Accordingly, the volume of conductive material 112 inside the trench is less than the volume of conducting material 112 in the deeper portion of the trench shown in FIGS. 5B and 5C, creating a partial shield electrode 520. In some implementations, the thickness of the insulating material 110, e.g., shield oxide, at the base of the trenches exhibits less variation than in some other implementations. Less variation in the oxide thickness can result in a more stable breakdown voltage.

FIG. 5E is a cross-sectional view along the cut line E-E′ of the central tapered trench shown in FIG. 5A, in accordance with some implementations of the present disclosure. The cut line E-E′ coincides with the tab 502, which restores the width of the tapered trench, creating a full shield electrode 530. The tab 502 is substantially symmetric about the longitudinal axis of the tapered trench. In some implementations, the full shield electrode 530 can have a width in a range of about 0.10 μm to about 1.0 μm and a depth in a range of about 1.0 μm to about 15.0 μm.

FIG. 5F is a cross-sectional view along the cut line F-F′, in accordance with some implementations of the present disclosure. The cut line F-F′ is aligned with the length of the central tapered trench shown in FIG. 5A. FIG. 5F shows the depth of the trench gradually decreasing along the taper until the tab 502 increases the corresponding depth of the shield electrode 108.

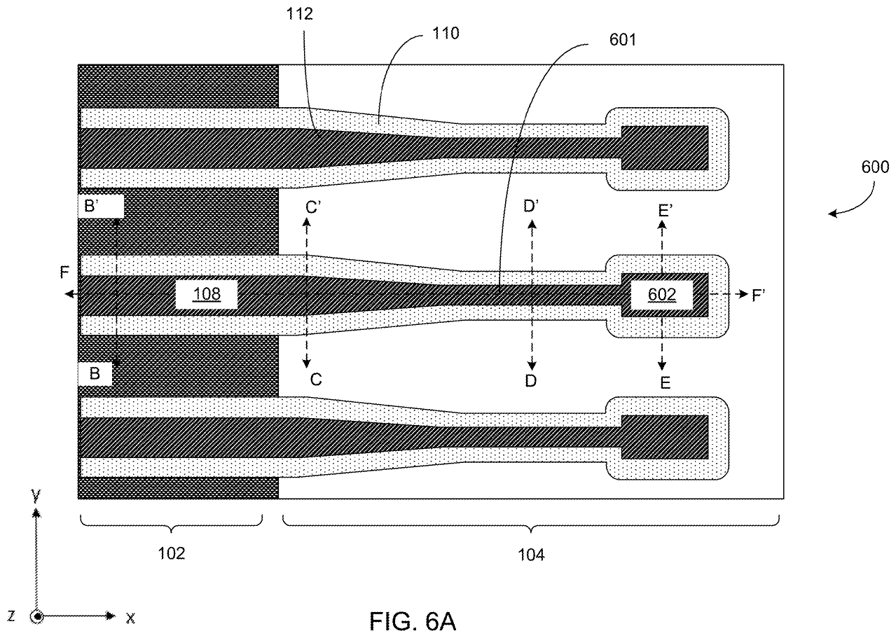

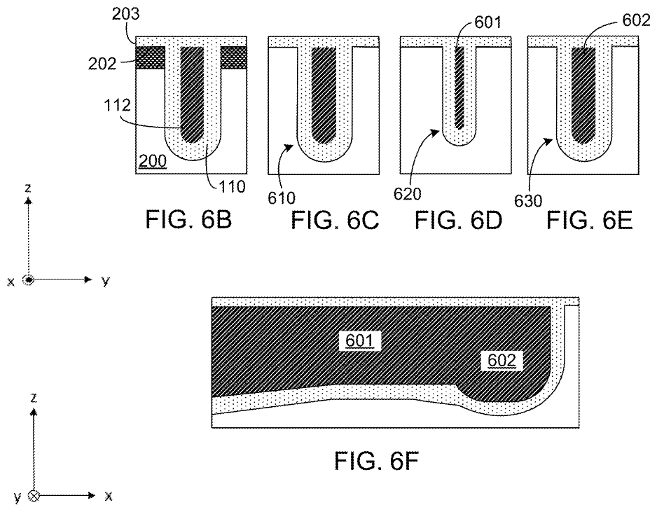

FIGS. 6A-6F are views of tapered trenches 600, in accordance with some implementations of the present disclosure. The tapered trenches 600 e.g., filled tapered trenches that serve as the shield electrodes 108, may represent a larger array of many tapered trench structures. In the implementation shown in FIGS. 6A-6F, each trench tapers to an extension 601 and a tab 602. The extension 601 maintains a uniform narrow width at the tapered end of the trench, which can help distribute charge and maintain a high breakdown voltage.

FIG. 6A is a top-down plan view of a group of three tapered trenches 600, in accordance with some implementations of the present disclosure. FIG. 6A shows the active area 102 and the termination region 104. The central tapered trench in FIG. 6A shows cross-sectional cuts at different locations along the tapered length (e.g., along the x-axis) of the central shield electrode 108. The cut lines correspond to the cross-sectional views shown in FIGS. 6B, 6C, 6D, and 6E. For example, cut line B-B′ corresponds to the transverse cross-sectional view shown in FIG. 6B; cut line C-C′ corresponds to the transverse cross-sectional view shown in FIG. 6C, and so on. Cut line F-F′ corresponds to a longitudinal cross-sectional view shown in FIG. 6F, wherein the cut line F-F′ is aligned with a longitudinal axis of the tapered trench, whereas the other cut lines, e.g., transverse cut lines, are aligned orthogonal to the longitudinal axis.

FIG. 6B is a cross-sectional view along the cut line B-B′ of the central tapered trench shown in FIG. 6A, in accordance with some implementations of the present disclosure. The cross-sectional view shown in FIG. 6B is within the active area 102, at the wide end of the tapered trench. FIG. 6B shows a substrate 200 and a doped region 202 near a top surface 203 of the substrate 200. In some implementations, the doped region 202 in the active area 102 can be a p-well. In some implementations, the substrate 200 may include an epitaxial layer, e.g., a layer of n-type epi silicon. FIG. 6B further illustrates the insulating material 110 and the conducting material 112 inside the parallel trenches forming the shield electrodes 108. FIG. 6B shows that, in the active area 102 at the widest part of the tapered trench, the thickness of the insulating material 110 lining the trench is substantially uniform. In some implementations, the thickness of the substantially uniform lining can be in a range of about 0.05 μm to about 1.5 μm. Accordingly, the volume of conductive material 112 inside the trench is maximized, creating a full shield electrode extending almost to the bottom of the trench. The internal structure of the tapered trench at the wide end as shown in FIG. 6B thus is similar to the example shown in FIG. 2B.

FIG. 6C is a cross-sectional view along the cut line C-C′ of the central tapered trench shown in FIG. 6A, in accordance with some implementations of the present disclosure. The cut line C-C′ is located outside the active area 102, in the termination region 104, but still coincides with the widest portion of the tapered trench. Consequently, the cross-sectional view shown in FIG. 6C shows a full shield electrode 610, similar to the cross-sectional view shown in FIG. 6B, except that the doped region 202 is not present in FIG. 6C.

FIG. 6D is a cross-sectional view along the cut line D-D′ of the central tapered trench shown in FIG. 6A, in accordance with some implementations of the present disclosure. The cut line D-D′ coincides with the narrow end of the tapered trench. FIG. 6D shows that in this location within the termination region 104 the trench is not as deep in the tapered region. Accordingly, the volume of conductive material 112 inside the trench is less than the volume of conducting material 112 in the deeper portion of the trench shown in FIGS. 6B and 6C, creating a partial shield electrode 620. In some implementations, the thickness of the insulating material 110, e.g., shield oxide, at the base of the trenches exhibits less variation than in some other implementations. Less variation in the oxide thickness can result in a more stable breakdown voltage.

FIG. 6E is a cross-sectional view along the cut line E-E′ of the central tapered trench shown in FIG. 6A, in accordance with some implementations of the present disclosure. The cut line E-E′ coincides with the tab 602, which restores the width of the tapered trench, creating a full shield electrode 630. In some implementations, the full shield electrode 630 can have a width in a range of about 0.1 μm to about 1.0 μm and a depth in a range of about 1.0 μm to about 15.0 μm.

FIG. 6F is a cross-sectional view along the cut line F-F′, in accordance with some implementations of the present disclosure. The cut line F-F′ is aligned with the length of the central tapered trench shown in FIG. 6A. FIG. 6F shows the depth of the conducting material 112 gradually decreasing along the tapered trench and then flattening out in the region where the trench width is uniformly narrow. FIG. 6F further shows that the tab 602 increases the corresponding depth of the shield electrode 108.

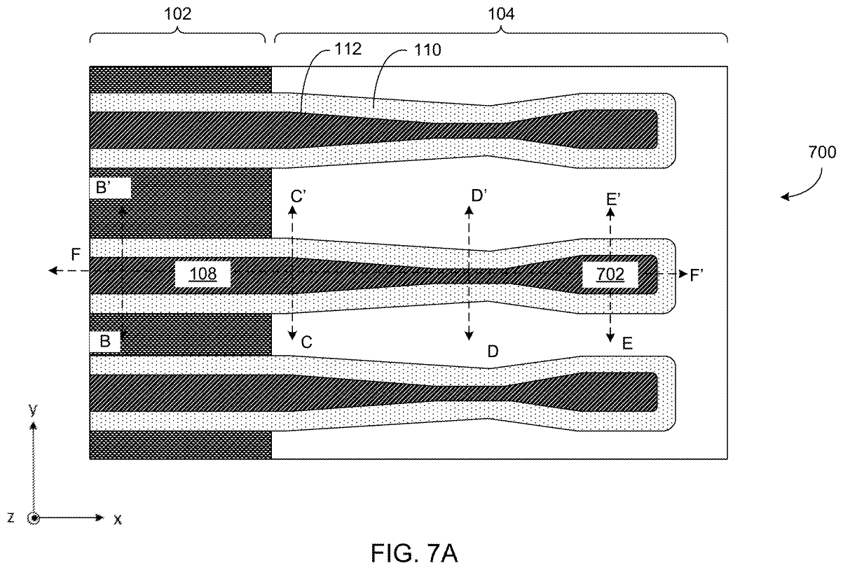

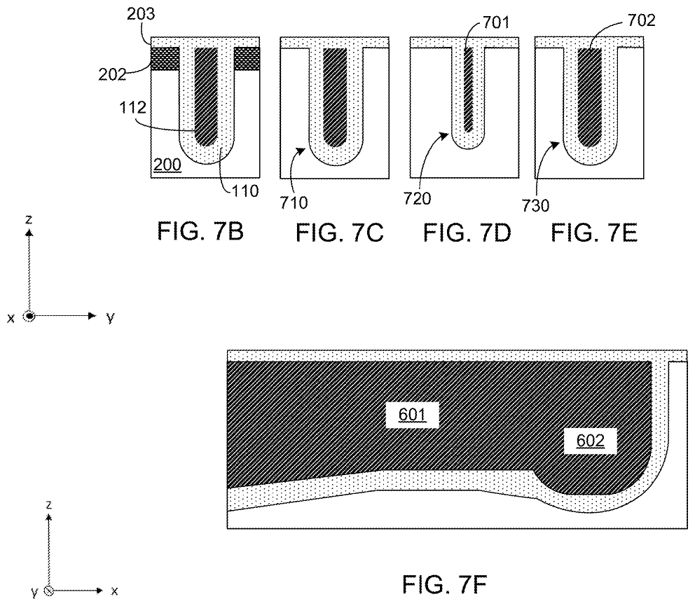

FIGS. 7A-7F are views of tapered trenches 700, in accordance with some implementations of the present disclosure. The tapered trenches 700 e.g., filled tapered trenches that serve as the shield electrodes 108, may represent a larger array of many tapered trench structures. In the implementation shown in FIGS. 7A-7F, each trench tapers to an extension 601 and then expands in a reverse taper 701 to a tab 702, creating a double-ended taper.

FIG. 7A is a top-down plan view of a group of three tapered trenches 700, in accordance with some implementations of the present disclosure. FIG. 7A shows the active area 102 and the termination region 104. The central tapered trench in FIG. 7A shows cross-sectional cuts at different locations along the tapered length (e.g., along the x-axis) of the central shield electrode 108. The cut lines correspond to the cross-sectional views shown in FIGS. 7B, 7C, 7D, and 7E. For example, cut line B-B′ corresponds to the transverse cross-sectional view shown in FIG. 7B; cut line C-C′ corresponds to the transverse cross-sectional view shown in FIG. 7C, and so on. Cut line F-F′ corresponds to a longitudinal cross-sectional view shown in FIG. 7F, wherein the cut line F-F′ is aligned with a longitudinal axis of the tapered trench, whereas the other cut lines, e.g., transverse cut lines, are aligned orthogonal to the longitudinal axis.

FIG. 7B is a cross-sectional view along the cut line B-B′ of the central tapered trench shown in FIG. 7A, in accordance with some implementations of the present disclosure. The cross-sectional view shown in FIG. 7B is within the active area 102, at the wide end of the tapered trench. FIG. 7B shows a substrate 200 and a doped region 202 near a top surface 203 of the substrate 200. In some implementations, the doped region 202 in the active area 102 can be a p-well. In some implementations, the substrate 200 may include an epitaxial layer, e.g., a layer of n-type epi silicon. FIG. 7B further illustrates the insulating material 110 and the conducting material 112 inside the parallel trenches forming the shield electrodes 108. FIG. 7B shows that, in the active area 102 at the widest part of the tapered trench, the thickness of the insulating material 110 lining the trench is substantially uniform. In some implementations, the thickness of the substantially uniform lining can be in a range of about 0.05 μm to about 1.5 μm. Accordingly, the volume of conductive material 112 inside the trench is maximized, creating a full shield electrode extending almost to the bottom of the trench. The internal structure of the tapered trench at the wide end, as shown in FIG. 7B, thus is similar to the example shown in FIG. 2B.

FIG. 7C is a cross-sectional view along the cut line C-C′ of the central tapered trench shown in FIG. 7A, in accordance with some implementations of the present disclosure. The cut line C-C′ is located outside the active area 102, in the termination region 104, but still coincides with the widest portion of the tapered trench. Consequently, the cross-sectional view shown in FIG. 7C shows a full shield electrode 710, similar to the cross-sectional view shown in FIG. 7B, except that the doped region 202 is not present in FIG. 7C.

FIG. 7D is a cross-sectional view along the cut line D-D′ of the central tapered trench shown in FIG. 7A, in accordance with some implementations of the present disclosure. The cut line D-D′ coincides with the uniformly narrow region of the tapered trench. FIG. 7D shows that in this location within the termination region 104, the trench is not as deep in the tapered region. Accordingly, the volume of conductive material 112 inside the trench is less than the volume of conducting material 112 in the deeper portion of the trench shown in FIGS. 7B and 7C, creating a partial shield electrode 720. In some implementations, the thickness of the insulating material 110, e.g., shield oxide, at the base of the trenches exhibits less variation than in some other implementations. Less variation in the oxide thickness can result in a more stable breakdown voltage.

FIG. 7E is a cross-sectional view along the cut line E-E′ of the central tapered trench shown in FIG. 7A, in accordance with some implementations of the present disclosure. The cut line E-E′ coincides with the tab 702, which restores the width of the tapered trench, creating a full shield electrode 730. In some implementations, the tab 702 has square corners. In some implementations, the full shield electrode 730 can have a width in a range of about 0.1 μm to about 1.0 μm and a depth in a range of about 1.0 μm to about 15.0 μm.

FIG. 7F is a cross-sectional view along the cut line F-F′, in accordance with some implementations of the present disclosure. The cut line F-F′ is aligned with the length of the central tapered trench shown in FIG. 7A. FIG. 7F shows the depth of the conducting material 112 gradually decreasing along the tapered trench and then leveling off in the narrow trench region. Then the depth increases again as the trench width expands toward the tab 702.

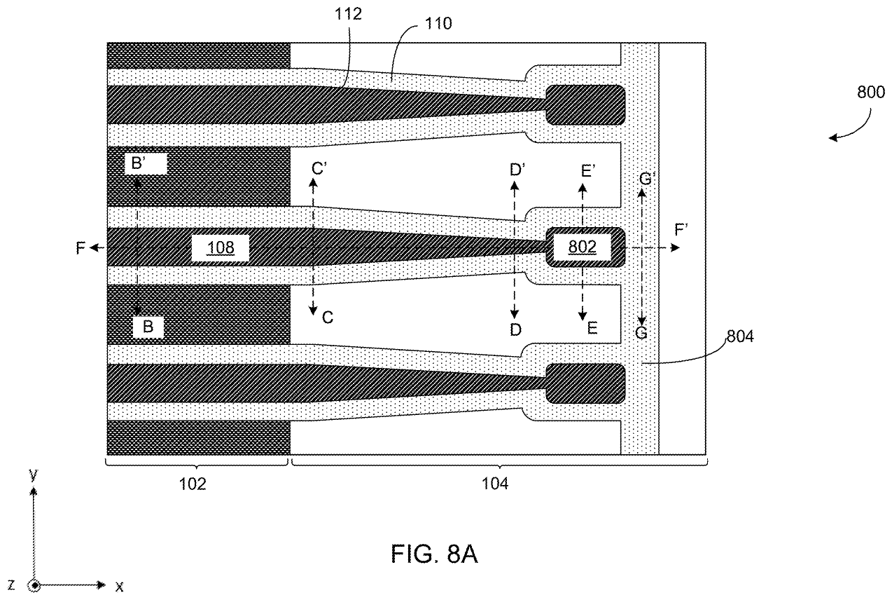

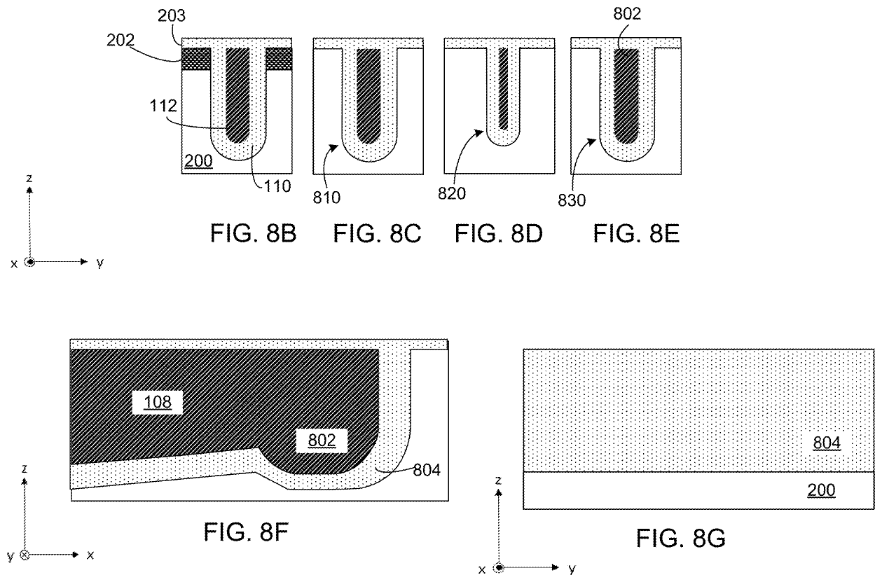

FIGS. 8A-8G are views of tapered trenches 800, in accordance with some implementations of the present disclosure. The tapered trenches 800 e.g., filled tapered trenches that serve as the shield electrodes 108, may represent a larger array of many tapered trench structures. In the implementation shown in FIGS. 8A-8G, each trench tapers to a tab 802, and the tabs 802 are connected by an oxide-filled trench 804. The oxide-filled trench helps to further distribute the electric potential at the ends of the tapered trenches 800.

FIG. 8A is a top-down plan view of a group of three tapered trenches 800, in accordance with some implementations of the present disclosure. FIG. 8A shows the active area 102 and the termination region 104. The central tapered trench in FIG. 8A shows cross-sectional cuts at different locations along the tapered length (e.g., along the x-axis) of the central shield electrode 108. The cut lines correspond to the cross-sectional views shown in FIGS. 8B, 8C, 8D, and 8E. For example, cut line B-B′ corresponds to the transverse cross-sectional view shown in FIG. 8B; cut line C-C′ corresponds to the transverse cross-sectional view shown in FIG. 8C, and so on. Cut line F-F′ corresponds to a longitudinal cross-sectional view shown in FIG. 8F, wherein the cut line F-F′ is aligned with a longitudinal axis of the tapered trench, whereas the other cut lines, e.g., transverse cut lines, are aligned orthogonal to the longitudinal axis.

FIG. 8B is a cross-sectional view along the cut line B-B′ of the central tapered trench shown in FIG. 8A, in accordance with some implementations of the present disclosure. The cross-sectional view shown in FIG. 8B is within the active area 102, at the wide end of the tapered trench. FIG. 8B shows a substrate 200 and a doped region 202 near a top surface 203 of the substrate 200. In some implementations, the doped region 202 in the active area 102 can be a p-well. In some implementations, the substrate 200 may include an epitaxial layer, e.g., a layer of n-type epi silicon. FIG. 8B further illustrates the insulating material 110 and the conducting material 112 inside the parallel trenches forming the shield electrodes 108. FIG. 8B shows that, in the active area 102 at the widest part of the tapered trench, the thickness of the insulating material 110 lining the trench is substantially uniform. In some implementations, the thickness of the substantially uniform lining can be in a range of about 0.05 μm to about 1.5 μm. Accordingly, the volume of conductive material 112 inside the trench is maximized, creating a full shield electrode extending almost to the bottom of the trench. The internal structure of the tapered trench at the wide end as shown in FIG. 8B thus is similar to the example shown in FIG. 2B.

FIG. 8C is a cross-sectional view along the cut line C-C′ of the central tapered trench shown in FIG. 8A, in accordance with some implementations of the present disclosure. The cut line C-C′ is located outside the active area 102, in the termination region 104, but still coincides with the widest portion of the tapered trench. Consequently, the cross-sectional view shown in FIG. 8C shows a full shield electrode 810, similar to the cross-sectional view shown in FIG. 8B, except that the doped region 202 is not present in FIG. 8C.

FIG. 8D is a cross-sectional view along the cut line D-D′ of the central tapered trench shown in FIG. 8A, in accordance with some implementations of the present disclosure. The cut line D-D′ coincides with the narrow end of the tapered trench. FIG. 8D shows that in this location within the termination region 104, the trench is not as deep in the tapered region. Accordingly, the volume of conductive material 112 inside the trench is less than the volume of conducting material 112 in the deeper portion of the trench shown in FIGS. 8B and 8C, creating a partial shield electrode 820. In some implementations, the thickness of the insulating material 110, e.g., shield oxide, at the base of the trenches exhibits less variation than in some other implementations. Less variation in the oxide thickness can result in a more stable breakdown voltage.

FIG. 8E is a cross-sectional view along the cut line E-E′ of the central tapered trench shown in FIG. 8A, in accordance with some implementations of the present disclosure. The cut line E-E′ coincides with the tab 802, which restores the width of the tapered trench, creating a full shield electrode 830. In some implementations, the tab 802 has rounded corners. In some implementations, the full shield electrode 830 can have a width in a range of about 0.1 μm to about 1.0 μm and a depth in a range of about 1.0 μm to about 15.0 μm.

FIG. 8F is a cross-sectional view along the cut line F-F′, in accordance with some implementations of the present disclosure. The cut line F-F′ is aligned with the length of the central tapered trench shown in FIG. 8A. FIG. FIG. 8F shows the depth of the trench gradually decreasing along the taper until the tab 802 increases the corresponding depth of the shield electrode 108.

FIG. 8G is a cross-sectional view along the cut line G-G′ next to the central tapered trench shown in FIG. 8A, in accordance with some implementations of the present disclosure. The cut line G-G′ coincides with the oxide filled trench 804.

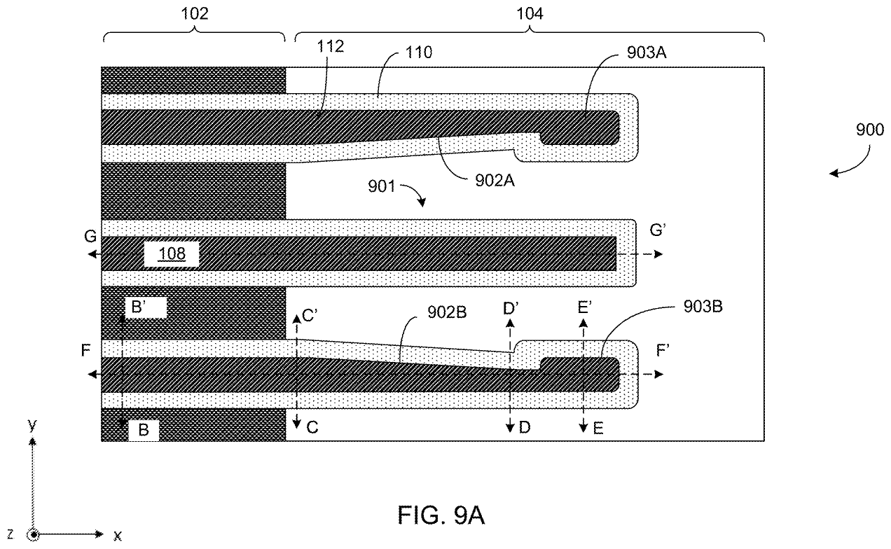

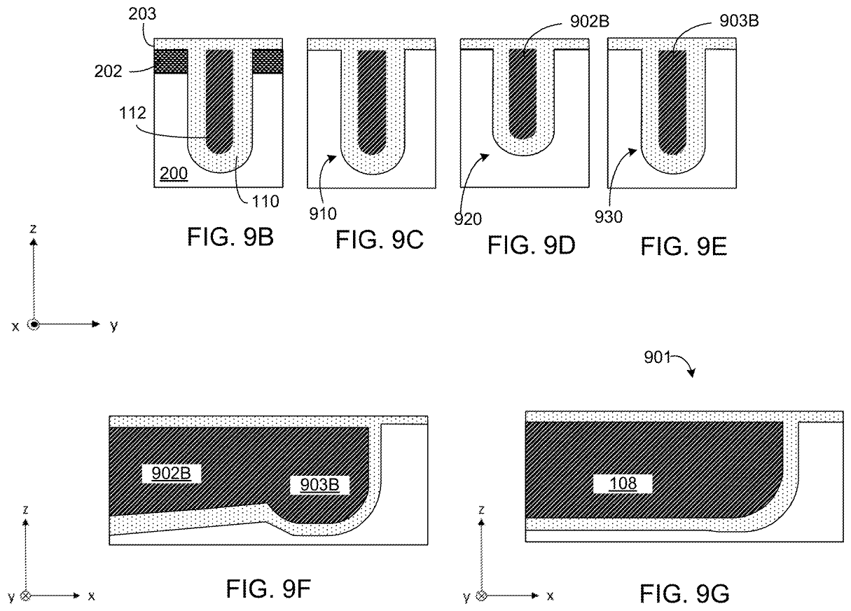

FIGS. 9A-9G are views of a tapered trench structure 900, in accordance with some implementations of the present disclosure. The tapered trench structure 900 e.g., filled tapered trenches that serve as the shield electrodes 108, may represent a larger array of many tapered trench structures. In the implementation shown in FIGS. 9A-9G, an array of trenches (three shown) includes a central trench 901 that is straight without a taper, a first trench adjacent to one side of the central trench 901, that has a single-sided taper 902A to a single-sided tab 903A, and a second trench, adjacent to an opposite side of the central trench 901, that has a single-sided taper 902B to a single-sided tab 903B. In some implementations, the single-sided tapers 902A and 902B are on the insides of the first and second trenches, facing the central trench 901. In some implementations, the single-sided tabs 903A and 903B extend from the ends of each of the first and second trenches, laterally outward in one direction, facing the central trench 901. In a larger array represented by the tapered trench structure 900, only the central trench 901 has straight sides. All of the other trenches are single-sided tapered trenches flanking the central trench 901, with single-sided tabs at the ends of the single-sided tapered trenches.

FIG. 9A is a top-down plan view of the tapered trench structure 900, in accordance with some implementations of the present disclosure. FIG. 9A shows the active area 102 and the termination region 104. The second trench adjacent to the central trench 901 in FIG. 9A shows cross-sectional cuts at different locations along the tapered length (e.g., along the x-axis). The cut lines correspond to the cross-sectional views shown in FIGS. 9B, 9C, 9D, 9E, 9F, and 9G. For example, cut line B-B′ corresponds to the transverse cross-sectional view shown in FIG. 9B; cut line C-C′ corresponds to the transverse cross-sectional view shown in FIG. 9C, and so on. Cut line F-F′ corresponds to a longitudinal cross-sectional view of the second trench, shown in FIG. 9F, wherein the cut line F-F′ is aligned with a longitudinal axis of the second tapered trench. Cut line G-G′ corresponds to a longitudinal cross-sectional view of the central trench 901, shown in FIG. 9G, wherein the cut line G-G′ is aligned with a longitudinal axis of the central trench 901. Other cut lines, e.g., transverse cut lines, are aligned orthogonal to the longitudinal axis.

FIG. 9B is a cross-sectional view along the cut line B-B′ through one of the tapered trenches shown in FIG. 9A, in accordance with some implementations of the present disclosure. The cross-sectional view shown in FIG. 9B is within the active area 102, at the wide end of the tapered trench. FIG. 9B shows a substrate 200 and a doped region 202 near a top surface 203 of the substrate 200. In some implementations, the doped region 202 in the active area 102 can be a p-well. In some implementations, the substrate 200 may include an epitaxial layer, e.g., a layer of n-type epi silicon. FIG. 9B further illustrates the insulating material 110 and the conducting material 112 inside the parallel trenches forming the shield electrodes 108. FIG. 9B shows that, in the active area 102 at the widest part of the single-sided tapered trench, the thickness of the insulating material 110 lining the trench is substantially uniform. In some implementations, the thickness of the substantially uniform lining can be in a range of about 0.05 μm to about 1.5 μm. Accordingly, the volume of conductive material 112 inside the trench is maximized, creating a full shield electrode extending almost to the bottom of the trench. The internal structure of the tapered trench at the wide end as shown in FIG. 9B thus is similar to previous examples, such as the example shown in FIG. 2B.

FIG. 9C is a cross-sectional view along the cut line C-C′ through one of the tapered trenches shown in FIG. 9A, in accordance with some implementations of the present disclosure. The cut line C-C′ is located outside the active area 102, in the termination region 104, but still coincides with the widest portion of the single-sided tapered trench. Consequently, the cross-sectional view shown in FIG. 9C shows a full shield electrode 910, similar to the cross-sectional view shown in FIG. 9B, except that the doped region 202 is not present in FIG. 9C.

FIG. 9D is a cross-sectional view along the cut line D-D′ through one of the tapered trenches shown in FIG. 9A, in accordance with some implementations of the present disclosure. The cut line D-D′ coincides with the narrow end of the single-sided tapered trench. FIG. 9D shows that in this location within the termination region 104, the insulating material 110 lining the trench is thinner but substantially uniform on the sides and the bottom of the trench. However, the trench is not as deep in the tapered region. Accordingly, the volume of conductive material 112 inside the trench is less than the volume of conducting material 112 in the deeper portion of the trench shown in FIGS. 9B and 9C, creating a partial shield electrode 920. In some implementations, the thickness of the insulating material 110, e.g., shield oxide, at the base of the trenches exhibits less variation than in some other implementations. Less variation in the oxide thickness can result in a more stable breakdown voltage.

FIG. 9E is a cross-sectional view along the cut line E-E′ through one of the single-sided tapered trenches shown in FIG. 9A, in accordance with some implementations of the present disclosure. The cut line E-E′ coincides with the single-sided tab 903B, which restores the width of the tapered trench, creating a full shield electrode 9830. In some implementations, the full shield electrode 930 can have a width in a range of about 0.1 μm to about 1.0 μm and a depth in a range of about 1.0 μm to about 15.0 μm.

FIG. 9F is a cross-sectional view along the cut line F-F′, in accordance with some implementations of the present disclosure. The cut line F-F′ is aligned with the length, along the x-axis, of one of the first or second tapered trenches shown in FIG. 9A. FIG. 9F shows the depth of the trench gradually decreasing along the taper until the single-sided tab 903B increases the corresponding depth of the shield electrode 108.

FIG. 9G is a cross-sectional view along the cut line G-G′, in accordance with some implementations of the present disclosure. The cut line G-G′ is aligned with the length of the central trench 901 shown in FIG. 9A. In some implementations, the central trench 901 is straight, not tapered. FIG. 9G shows a substantially uniform depth of the conducting material 112 of the shield electrode 108 along the length of the central trench, consistent with a trench of uniform width.

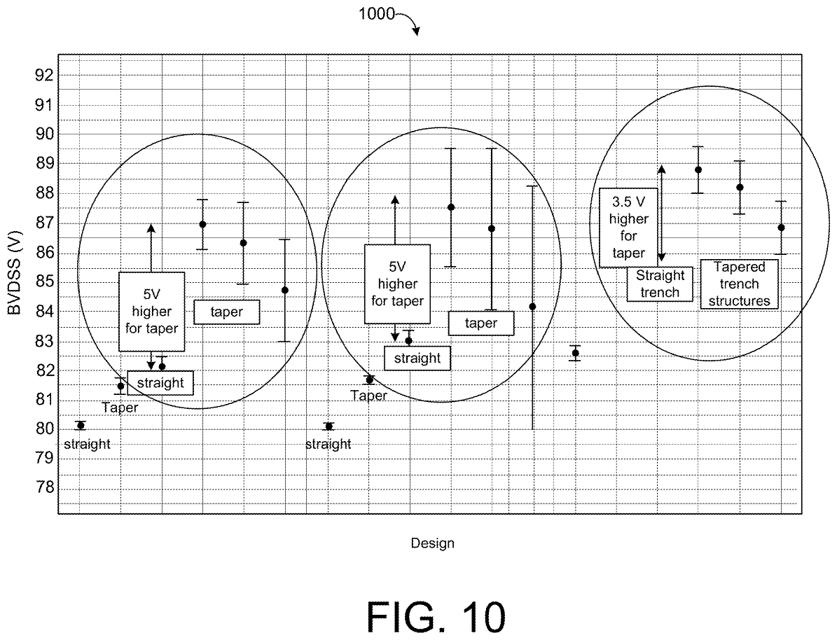

FIG. 10 is a plot 1000 of electrical test data obtained from various types of tapered trench structures, in accordance with some implementations of the present disclosure. The use of tapered trench termination shows about a 3 V-5 V increase in breakdown voltage compared with a straight trench having no taper. In some implementations, the improvement in breakdown voltage can vary somewhat depending on the mask design, e.g., on the critical dimensions (CDs) and the type of taper used; the presence of epitaxial layers; and other charge balance parameters. Improvement in breakdown voltage has been demonstrated for both recessed polysilicon shield electrodes 108, having trench structures like those shown in FIGS. 3A-3C, and surface polysilicon shield electrodes 108, having trench structures like those shown in FIGS. 2A-2D.

FIG. 11 is a cross-sectional diagram that illustrates a pair of adjacent MOSFET devices 1100 disposed in the active area 102, according to an implementation of the present disclosure The pair of MOSFET devices 1100 includes a MOSFET device MOS1 and a MOSFET device MOS2. Because the MOSFET devices MOS1, MOS2 have similar features, the MOSFET devices MOS1, MOS2 will generally be discussed in terms of a single MOSFET device MOS2 (that is mirrored in the other MOSFET device MOS1 and/or mirrored within the MOSFET device MOS2). The pair of MOSFET devices 1100 can be, for example, relatively high voltage devices (e.g., greater than 30V, 60V devices, 100V devices, 300V devices). In some implementations, the MOSFET devices MOS1 and the MOS2 are spaced in accordance with a pitch PH. As shown in FIG. 11 the pair of MOSFET devices 1100 is formed within an epitaxial layer 1130 (e.g., an N-type doped epitaxial layer 1130). Each MOSFET device MOS1, MOS2 includes a trench 1105, a gate dielectric 1118, a gate electrode 1120, and source regions 1133. A mesa region 1150 extends between MOS1 and MOS2. The source regions 1133 (e.g., N+source regions) are disposed above body regions 1134 (e.g., P-type body regions 1134) that can be formed in the epitaxial layer 1130. The epitaxial layer can be formed on, or in, the substrate 200, not shown (e.g., an N+substrate 200). The trench 1105 can extend through the body region 1134 and can terminate in a drift region 1137 within the epitaxial layer 1130 (also can be referred to as an epitaxial region). The trench 1105 includes a dielectric 1110 (which can include one or more dielectric layers such as the gate dielectric 1118) disposed within the trench 1105. A gate electrode 1120 and a shield electrode 1121 are disposed within the trench 1105.

The pair of MOSFET devices 1100 can be configured to operate by applying a voltage (e.g., a gate voltage) to the gate electrode 1120 of, for example, the MOSFET device MOS2 to turn on MOS2 by forming a channel adjacent to the gate dielectric 1118, e.g., gate oxide, so that current may flow between the source region 1133 and a drain contact (not shown). In accordance with the termination implementations described herein, the performance characteristics and dimensions of the pair of MOSFET devices 1100 can be improved. For example, an ON-resistance of the pair of MOSFETs devices 1100 can be reduced by approximately 50%, or more. This is achieved by decreasing the pitch PH between the MOSFET device MOS1 and the MOSFET device MOS2 by approximately 20%, or more, by decreasing the width of the mesa region 1150, with substantially no decrease in breakdown voltage, while the pair of MOSFET devices 1100 is OFF. The decrease in the ON-resistance of the MOSFET device 1100 can be realized through an increase, e.g., a 30% increase, in dopant concentration within the epitaxial layer 1130 which is enabled by the termination implementations described herein.

As described above, various implementations of semiconductor devices that include shielded gate electrodes featuring tapered trench structures can increase and stabilize breakdown voltages to improve reliability in high-power applications. The tapered trenches can include arrangements of double-ended tapers, single-sided tapers, end tabs, or a simple taper to a point. Such trench configurations can result in an increase in breakdown voltage between about 3 V and about 5 V.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor device processing techniques associated with semiconductor substrates including, but not limited to, for example, silicon (Si), silicon carbide (SiC), gallium arsenide (GaAs), gallium nitride (GaN), and/or so forth.

While certain features of the described implementations have been illustrated as described herein, many modifications, substitutions, changes, and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

1. An apparatus comprising:
a trench having a first portion in an active area and a second portion in a termination region, the trench having a vertical depth within a semiconductor substrate and having a longitudinal axis extending from within the active area into the termination region;
a dielectric lining disposed in the trench; and
a conductive electrode disposed in the trench over the dielectric lining, the conductive electrode having, along the longitudinal axis, a uniform shape within the first portion, and a tapered shape within the second portion.

2. The apparatus of claim 1, further comprising a tab intersecting an end of the second portion, the tab extending in a direction transverse to the longitudinal axis.

3. The apparatus of claim 2, wherein the tab is substantially symmetric about the longitudinal axis.

4. The apparatus of claim 1, wherein the conductive electrode includes polysilicon.

5. The apparatus of claim 1, wherein the semiconductor substrate includes silicon carbide.

6. The apparatus of claim 1, being a shield structure of a shielded gate metal oxide semiconductor field effect transistor.

7. A device, comprising:
a substrate having a diffusion region formed therein;
a source in the diffusion region;
a drain in the diffusion region; and
a shield structure formed in a trench in the substrate, the trench having a dielectric liner, wherein the shield structure extends out from within the diffusion region and tapers to a terminus.

8. The device of claim 7, wherein the terminus is a point.

9. The device of claim 7, wherein the terminus includes at least one of a tab, an extension, and a reverse taper.

10. The device of claim 9, wherein the terminus includes a tab that extends in a direction orthogonal to the trench.

11. The device of claim 7, wherein an aspect ratio characterizing a maximum width of the shield structure in the diffusion region and a minimum width of the shield structure at the terminus is about 3:1.

12. The device of claim 7, wherein a first side of the shield structure is tapered, and a second side, opposite the first side, is straight.

13. A structure in a substrate, the structure comprising:
a central shield structure;
a first shield structure adjacent to one side of the central shield structure; and
a second shield structure adjacent to an opposite side of the central shield structure,
wherein the central shield structure is not tapered, the first shield structure has a tapered first side, and the second shield structure has a tapered second side.

14. The structure of claim 13, wherein the first shield structure includes a first end tab extending laterally outward from the tapered first side and the second shield structure includes a second end tab extending laterally outward from the tapered second side.

15. The structure of claim 14, wherein the first end tab and the second end tab have rounded corners.

16. The structure of claim 13, wherein each one of the central shield structure, the first shield structure, and the second shield structure extends into the substrate to a prescribed depth.

17. The structure of claim 16, wherein the prescribed depth varies along a length of the first shield structure.

18. The structure of claim 16, wherein the prescribed depth is in a range of about 1.0 μm to about 15.0 μm.

19. The structure of claim 16, wherein the first shield structure and the second shield structure each have a minimum depth coinciding with a maximum taper.

20. The structure of claim 16, wherein the first shield structure has a width in a range of about 0.1 μm to about 1.0 μm.
